(19) United States
(12) Patent Application Publication
(10) Pub. No.: US 2006/0170079 A1
(43) Pub. Date: Aug. 3, 2006

(54) Integrated circuit device having encapsulant dam with chamfered edge

(76) Inventors: John McKenna Brennan, Pittsford, NY (US); Patrick J. Carberry, Laurys Station, PA (US); Joseph Michael Freund, Fogelsville, PA (US); George John Libricz JR., Bethlehem, PA (US); Ralph S. Moyer, Robesonia, PA (US)

Correspondence Address: RYAN, MASON & LEWIS, LLP, 90 FOREST AVENUE, LOCUST VALLEY, NY, 11560, US

(21) Appl. No.: 11/048,968

(22) Filed: Feb. 2, 2005

(51) Int. Cl. H01L 23/495

(52) U.S. Cl. 257/666

(57) ABSTRACT

An integrated circuit device is provided having a substrate, at least one integrated circuit element and a leadframe. The integrated circuit element and the leadframe are disposed on the substrate. The leadframe has at least one lead and at least one encapsulant dam disposed on the at least one lead. The encapsulant dam has at least one chamfered edge to provide clearance for a wire feed during a wire-bonding process.

### FIELD OF THE INVENTION

The present invention relates generally to integrated circuits and, more particularly, to integrated circuit packaging techniques.

### BACKGROUND OF THE INVENTION

An integrated circuit is generally fabricated utilizing a chip of silicon or other semiconductor material, also referred to as a die. A die is typically installed in a package, and electrically connected to leads of the package. These leads may then be soldered to traces on a printed wiring board (PWB), or other circuit mounting structure, to provide connections between the die and external circuitry.

A number of different cavity packages are known in the art, and may be used, by way of example, to package a Radio Frequency Laterally Diffused Metal Oxide Semiconductor (RFLDMOS) device or other integrated circuit device. In one type of cavity package, a die is sealed inside a protective enclosure. Leads penetrate the walls of the protective enclosure so that they may be electrically connected to the die. These packages are known in the electronics industry as “air-cavity packages,” since the die resides in a hollow air-filled cavity inside the enclosure.

The two major wire-bonding processes used for electronic package interconnects are wedge bonding and ball bonding. The wedge-bonding process has traditionally been used to form the package interconnects of RF integrated circuits due the ease in forming the wire bond profiles necessary for optimal RF performance.

An encapsulant dam is typically arranged on the package lead to prevent encapsulant from entering the cavity of the package. The encapsulant dam also assists in retaining the leads and strengthening the package. The wider the cross-sectional base of the encapsulant dam, the better suited the encapsulant dam is to provide lead retention and package strength. However, the encapsulant dam must also provide suitable wire feed clearance for bonds to be placed on a wire bond land area of the portion of the lead penetrating inside the cavity beyond the encapsulant dam. Previous attempts to solve the problem of providing a sufficient cross-sectional encapsulant dam width while also allowing for wire feed clearance include wider encapsulant dam cross-sections at the expense of the wire bond land areas and hermetic packaging that does not require encapsulant or encapsulant dams.

Wider encapsulant dam cross-sections that allow for limited wire feed clearance may require the use of either a deep reach wedge bonder or a ball bonder. Most deep reach wedge bonders use a “table tear” wire tear method that exerts a considerable amount of energy on the die, capacitors and substrate. This technique has been known to damage the RFLDMOS die and capacitors. Ball bonders are difficult to use on high frequency, high power RF applications due to the increased tendency of their resulting wire bonds to incur coupling. Ball bonders also typically require the use of gold bonding wire, while wedge bonders often use aluminum.

Hermetic packages are more expensive than air-cavity packages utilizing encapsulant, and require additional process steps such as lid sealing and leak check. These additional steps require increased capital equipment, longer cycle times and yield points. An RF power amplifier in a hermetic package also typically requires a “glob top” to prevent moisture from causing current leakage in the device.

Thus, a need exists for an integrated circuit device having an encapsulant dam that provides lead retention and package strength while also enabling the wedge-bonding process.

### SUMMARY OF THE INVENTION

The present invention provides an integrated circuit device that provides sufficient wire feed clearance during wire bonding, as well as lead retention and package strength, by utilizing an encapsulant dam with a chamfered edge.

In accordance with one aspect of the invention, an integrated circuit device is provided having a substrate, at least one integrated circuit element and a leadframe. The integrated circuit element and the leadframe are disposed on the substrate. The leadframe has at least one lead and at least one encapsulant dam disposed on the at least one lead. The encapsulant dam has at least one chamfered edge to provide clearance for a wire feed during a wire-bonding process.

In accordance with another aspect of the invention, a leadframe for use with an integrated circuit device is provided, having at least one lead and at least one encapsulant dam disposed on the at least one lead. The encapsulant dam has at least one chamfered edge to provide clearance for a wire feed during a wire-bonding process.

In accordance with a further aspect of the invention, a method of producing an integrated circuit device is provided. At least one integrated circuit element is attached to a substrate. A leadframe, having at least one lead and at least one encapsulant dam disposed on the at least one lead, is attached to the substrate. The at least one encapsulant dam has at least one chamfered edge to provide clearance for a wire feed during a wire-bonding process. The at least one integrated circuit element is electrically connected to the at least one lead of the leadframe.

In accordance with additional illustrative embodiments of the present invention, the encapsulant dam of the integrated circuit device has a height above a substrate of the integrated circuit device that is greater than a height of the highest wire bond above the substrate of the integrated circuit device. Further, the chamfered edge of the encapsulant dam is disposed at an upper corner of a cross-section of the encapsulant dam on a side closest to an integrated circuit element of the integrated circuit device.

Advantageously, the illustrative embodiments of the present invention provide a sufficient cross-sectional encapsulant dam width while also allowing for wire feed clearance during a wire-bonding process. Thus, the illustrative embodiments of the present invention provide lead retention and package strength while also enabling a wedge-bonding process.

These and other objects, features, and advantages of the present invention will become apparent from the following detailed description of the illustrative embodiments thereof, which is to be read in connection with the accompanying drawings.

### BRIEF DESCRIPTION OF THE DRAWINGS

FIG. 1 is a diagram illustrating a partial side view of an integrated circuit device having an encapsulant dam, according to an embodiment of the present invention;

FIG. 2 is a diagram illustrating a partial side view of an integrated circuit device having an encapsulant dam with a chamfered edge, according to an embodiment of the present invention;

FIG. 3 is a diagram illustrating a partial perspective view of an integrated circuit device having an encapsulant dam with a chamfered edge, according to an embodiment of the present invention; and

FIG. 4 is a flow diagram illustrating a integrated circuit production methodology for an integrated circuit device having an encapsulant dam with a chamfered edge, according to an embodiment of the present invention.

### DETAILED DESCRIPTION

As will be described in detail below, the present invention in the illustrative embodiment provides an integrated circuit device that provides sufficient wire feed clearance at a lead during wire bonding, as well as lead retention and package strength, by utilizing an encapsulant dam with a chamfered edge. A chamfered edge, as described herein, includes an edge or corner that is removed by means, such as, for example chamfering, beveling, fluting, or cutting a groove or furrow in, in order to provide greater clearance for a wire feed. Thus, a chamfered edge may be described as one at which two surfaces meet at an angle different than 90 degrees.

Referring initially to FIG. 1, a diagram illustrates a partial side view of an integrated circuit device having an encapsulant dam, according to an embodiment of the present invention. A die 102 is disposed on a substrate 104. In a preferred embodiment of the present invention, substrate 104 is a copper base. A spacer 106 is disposed on substrate 104 proximate to die 102. Lead 108 is disposed on spacer 106 and above die 102 in the side view. An encapsulant dam 110 is disposed on lead 108 so that a portion of lead 108, namely a wire bond land area 112, protrudes beyond encapsulant dam 110, toward die 102. Spacer 106, lead 108 and encapsulant dam 110 may all be considered part of a leadframe of the integrated circuit device. A wire bond 114 connects die 102 to wire bond land area 112 of lead 108.

As described above, the width of encapsulant dam is preferably as wide as possible to help retain the lead and add strength to the package. Encapsulant dam 110 is also preferably disposed above substrate 104 and spacer 106 to provide the greatest strength to the package. Thus, any increase in encapsulant dam 110 width results in a decrease in wire bond land area 112 of lead 108, since width would be increased toward die 102. The height of encapsulant dam 110 correlates to the height of the highest tuning wire of the integrated circuit device. Specifically, the height of encapsulant dam 110 above die 102 is slightly greater than the height of the highest wire bond profile above die 102. In many embodiments of the present invention, encapsulant dam 110 and spacer 106 may surround or encircle die 110, defining part of a wall of the air-cavity chamber of the integrated circuit device. Therefore, the height of encapsulant dam 110 corresponds to the highest wire bond profile so that a lid or cover placed on encapsulant dam 110 during integrated circuit device processing and defining the air-cavity chamber does not interfere with any of the wire bonds of the integrated circuit device.

FIG. 1 also demonstrates what would occur during a “forward-up” wedge bonding process. A bonding tool having a wire bonding wedge 116 is shown in the process of bonding a wire bond 114 to wire bond land area 112 of lead 108. Encapsulant dam 110 as shown, would interfere with a wire feed 120 of the wire-bonding process. The wire feed angle for this process in the illustrative embodiment may be approximately 38 degrees, although other angles can be used. This allows for the widest process window when tuning the bond wires for minimal coupling, as well as the lowest inter-metal dielectric (IMD) and highest output power. In another embodiment the wire feed angle may be approximately 45 degrees. However, as is apparent from the figure, the wire feed at either of these example angles will be at least partially blocked by the encapsulant dam.

The wire feed clearance problem maybe solved by reverse bonding, and placing the first bond on the lead and the second bond on the die. However, this may cause substrate cracks during qualification using, for example, an ultra-thin 2 mil transistor die. The disadvantages of the use of a deep reach wedge wire bonder and a ball bonder are described above. Further, as the feed angle of the wire bonder increases, producing the required tuning loops while bonding becomes more difficult.

The wire bonding process for RF discrete power amplifiers utilizes a “forward-up” wedge bonding process which places the first bond on die 102, for example, primary 2-mil RFLDMOS die, and the more aggressive second bond on wire bond land area 112 of lead 108. This technique exerts minimal energy on, for example, the RFLDMOS die, thereby reducing the probability of damage to die 102. This technique also produces the shortest possible output wire, which yields an integrated circuit device with the highest possible gain and output power.

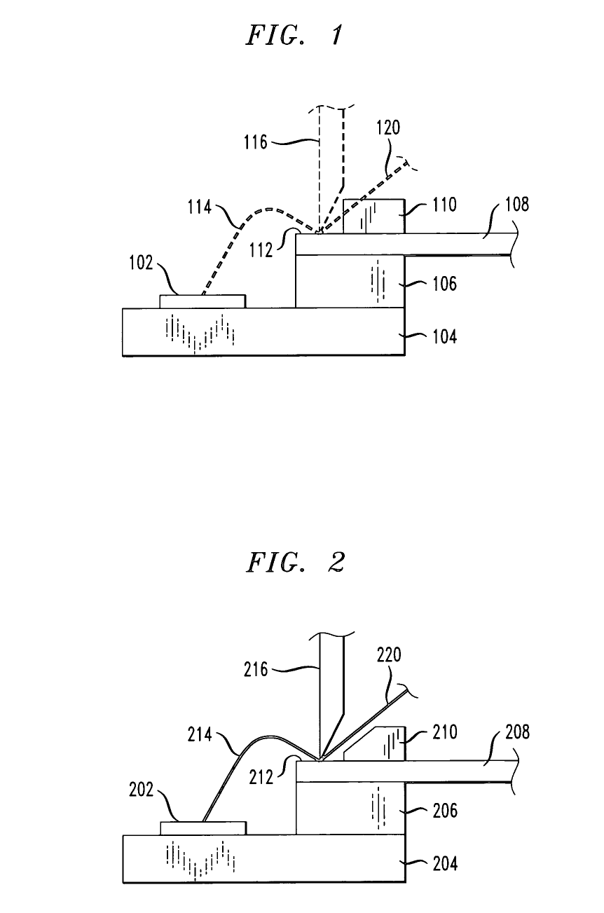

Referring now to FIG. 2, a diagram illustrates a partial side view of an integrated circuit device having an encapsulant dam with a chamfered edge, according to an embodiment of the present invention. The integrated circuit device includes a similar configuration to that of FIG. 1, including die 202, substrate 204, spacer 206, lead 208, encapsulant dam 210, wire bond land area 212, wire bond 214, wire bonding wedge 216, and wire feed 220.

Encapsulant dam 210 has a chamfered edge at an upper corner of its cross-section on a side closest to die 202. This chamfered edge allows the wire-bonding process to proceed without encapsulant dam 210 interfering with wire feed 220. Encapsulant dam 210 also maintains its width at its base at lead 208 and its height above the highest wire bond. Thus, encapsulant dam 210 provides the largest cross-sectional area possible for lead retention and package strength and rigidity, while also maintaining wire bond land area 212.

The angle at which the edge of encapsulant dan 210 is chamfered may be based on the wire feed angle desired in performing the wire-bonding process. For example, if it is desirable to perform wire bonding with a wire feed angle of 38 degrees, encapsulant dam 210 may be chamfered at an angle of 38 degrees. This would also enable wire bonding with wire feed angles greater than 38 degrees. However, while encapsulant dams chamfered at angles lower than that of the wire feed may provide wire feed clearance they also provide smaller cross-sectional areas than necessary, which may result in less package strength and rigidity. Therefore, it is preferable to match the wire feed angles and chamfering angles as close as possible.

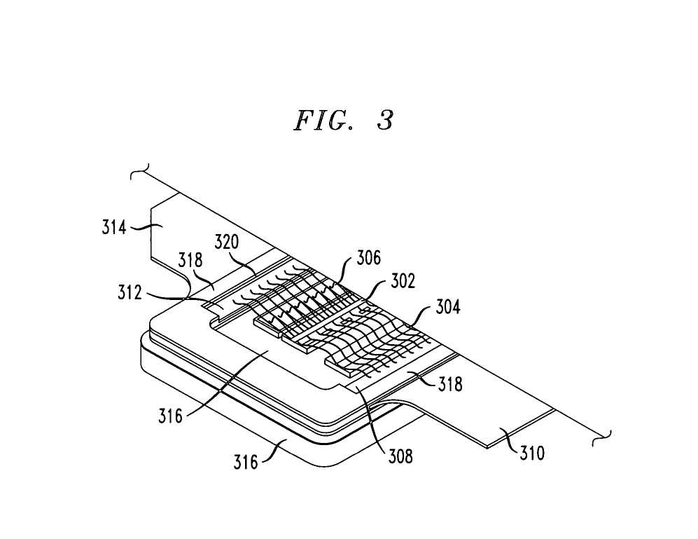

Referring now to FIG. 3, a diagram illustrates a partial perspective view of an integrated circuit device having a capacitor-die-capacitor arrangement of circuit elements within an air-cavity package, according to an embodiment of the present invention. The integrated circuit device is illustrated without a lid or cover so that the internal circuit elements and connections are visible. A die 302 is wire bonded to a first capacitor 304 on one side, and a second capacitor 306 on another side. First capacitor 304 is wire bonded to a first wire bond land area 308 of a first lead 310. Die 302 is wire bonded to a second wire bond land area 312 of a second lead 314. Die 302, first capacitor 304 and second capacitor 306 are disposed on a substrate 316. While a capacitor-die-capacitor arrangement is shown in this embodiment, the integrated circuit device may comprise any number or configuration of integrated circuit elements within its air-cavity chamber. For example, the integrated circuit device may have a single die in the air-cavity chamber as illustrated in FIGS. 1 and 2, or the integrated circuit device may have multiple capacitor-die-capacitor arrangements within a single air-cavity chamber.

An encapsulant dam 318 is disposed on first lead 310 and second lead 314, having a chamfered edge 320 on its upper, inner edge, to provide wire feed clearance for the wire bonding process at first wire bond land area 308 and second wire bond land area 312. Chamfered edge 320 is shown on two opposing sides of the integrated circuit device because it is at these sides that first lead 310 and second lead 314 protrude into the air-cavity chamber and are electrically connected to the internal circuit elements, namely die 302 and first capacitor 304. Additional embodiments may have an encapsulant dam 318 with a chamfered edge 320 that completely encircles or surrounds the internal circuit elements, because leads are electrically connected to the circuit elements at all sides of the integrated circuit device.

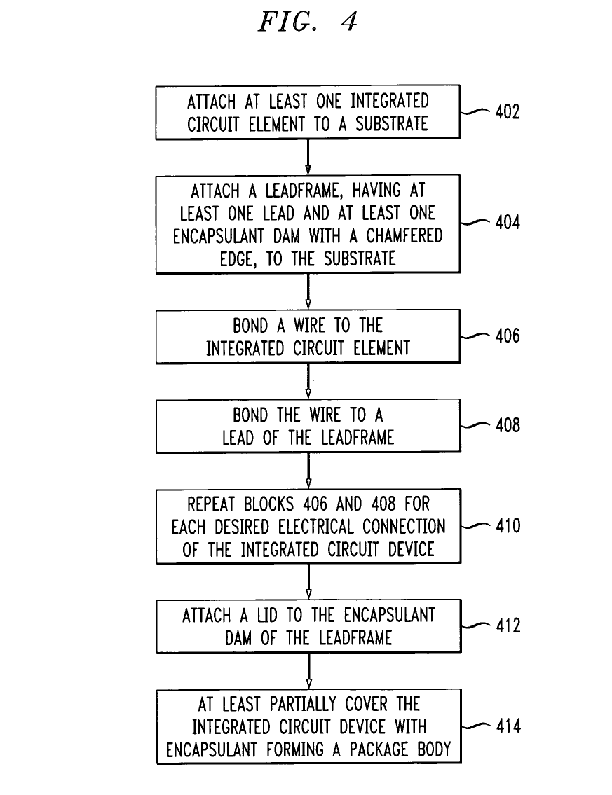

A flow diagram is illustrated in FIG. 4, showing an integrated circuit device production methodology, for an integrated circuit device having an encapsulant dam with a chamfered edge, according to an embodiment of the present invention. In block 402, at least one integrated circuit element is attached to a substrate. The integrated circuit element may be, for example, a die or a capacitor as shown in FIGS. 1-3. This attachment is achieved using, for example, epoxy or solder, as will be appreciated by those skilled in the art. In block 404, a leadframe, having one or more leads, is attached to the substrate. The leadframe generally surrounds or encircles the circuit element on the substrate, and the leads protrude into what will be considered the air-cavity chamber. The leadframe includes an encapsulant dam on the leads of the leadframe. The encapsulant dam has at least one chamfered edge to provide clearance for a wire feed during a wire-bonding process. The chamfered edge is preferably at an upper corner closest to the circuit element or the air-cavity chamber.

In block 406, a wire is bonded to the integrated circuit element on the substrate. In block 408, the wire is bonded to a lead of the leadframe. The wire-bonding process is preferably a “forward-up” wedge-bonding process, as described above, which repeats for all desired electrical connections of the integrated circuit device in block 410. In block 412, a lid maybe attached to the encapsulant dam of the leadframe enclosing the air-cavity chamber. The lid is preferably attached with out contacting the wire bonds of the integrated circuit device. Therefore, the encapsulant dam of the leadframe should be higher above the substrate than the highest wire bond profile. Finally, in block 414, the integrated circuit device is at least partially covered with encapsulant forming a package body, and enclosing the air-cavity chamber. The encapsulant is prevented from entering the air-cavity chamber by the encapsulant dam and the lid.

Accordingly, as described herein, the present invention in the illustrative embodiment provides an integrated circuit device that provides sufficient wire feed clearance at a lead during wire bonding, as well as, lead retention and package strength, by utilizing an encapsulant dam with a chamfered edge.

Additional embodiments of the present invention may incorporate various numbers and combinations of dies, capacitors, leads, or other circuit elements, arranged in various configurations within a given integrated circuit. The positioning and number of dies, capacitors and other elements will of course result in various numbers and configurations of wire bonds and associated bond sites. The techniques of the present invention may also be used in non-RF integrated circuits. Further, additional embodiments may incorporate various wire bond shapes, wire bond heights, wire diameters and other wire characteristics. Encapsulant dam profiles may vary to include many different encapsulant dam widths, heights, and chamfering angles. Finally, the placement of the encapsulant dam in the integrated circuit device may vary according to where in the integrated circuit device sufficient wire feed clearance is needed.

Regarding integrated circuits in general, a plurality of identical die are typically formed in a repeated pattern on a surface of a semiconductor wafer. Each die may include other structures or circuits. The individual die are cut or diced from the wafer, then packaged as an integrated circuit. One skilled in the art would know how to dice wafers and package die to produce integrated circuits. Integrated circuits so manufactured are considered part of this invention.

Therefore, although illustrative embodiments of the present invention have been described herein with reference to the accompanying drawings, it is to be understood that the invention is not limited to those precise embodiments, and that various other changes and modification may be made by one skilled in the art without departing from the scope or spirit of the invention.

What is claimed is:

1. An integrated circuit device comprising:
a substrate;
at least one integrated circuit element disposed on the substrate; and
a leadframe disposed on the substrate and having at least one lead and at least one encapsulant dam disposed on the at least one lead, wherein the at least one encapsulant dam has at least one chamfered edge to provide clearance for a wire feed during a wire-bonding process.

2. The integrated circuit device of claim 1, wherein the at least one integrated circuit element comprises at least one of a die and a capacitor.

3. The integrated circuit device of claim 1, further comprising at least one wire bond connecting the at least one integrated circuit element to the at least one lead.

4. The integrated circuit device of claim 3, wherein the at least one encapsulant dam has a height above that substrate that is greater than a height of the at least one wire bond above the substrate.

5. The integrated circuit device of claim 1, wherein the at least one encapsulant dam completely surrounds the at least one circuit element.

6. The integrated circuit device of claim 5, further comprising a lid disposed on the at least one encapsulant dam, which defines an air-cavity chamber of the integrated circuit device.

7. The integrated circuit device of claim 1, further comprising a package body formed from encapsulant, at least partially enclosing the integrated circuit device.

8. The integrated circuit device of claim 1, wherein the chamfered edge of the at least one encapsulant dam is disposed at an upper corner of a cross-section of the encapsulant dam on a side closest to the at least one integrated circuit element.

9. The integrated circuit device of claim 1, wherein the chamfered edge of the at least one encapsulant dam provides wire feed clearance for a wire feed angle of approximately 30-50 degrees.

10. The integrated circuit device of claim 1, wherein an angle of the chamfered edge of the at least one encapsulant dam substantially matches a wire feed angle of the wire-bonding process.

11. The integrated circuit device of claim 1, wherein the chamfered edge of the at least one encapsulant dam provides wire feed clearance when bonding to the at least one lead of the leadframe.

12. A leadframe for use with an integrated circuit device comprising at least one lead and at least one encapsulant dam disposed on the at least one lead, wherein the at least one encapsulant dam has at least one chamfered edge to provide clearance for a wire feed during a wire-bonding process.

13. The leadframe of claim 12, wherein the at least one chamfered edge is disposed at an upper corner of a cross-section of the encapsulant dam on a side closest to a wire bond land area of the at least one lead.

14. A method of producing an integrated circuit device with at least one encapsulant dam having a chamfered edge comprising the steps of:
attaching at least one integrated circuit element to a substrate;
attaching a leadframe to the substrate, wherein the leadframe comprises at least one lead and at least one encapsulant dam disposed on the at least one lead, wherein the at least one encapsulant dam has at least one chamfered edge to provide clearance for a wire feed during a wire-bonding process; and
electrically connecting the at least one integrated circuit element to the at least one lead of the leadframe.

15. The method of claim 14, wherein the step of electrically connecting the at least one integrated circuit element to the at least one lead of the leadframe comprises the steps of:
bonding at least one wire to the at least one integrated circuit element; and
bonding the at least one wire to at least one lead of the leadframe.

16. The method of claim 14, wherein, in the step of attaching a leadframe to the substrate, the at least one encapsulant dam completely surrounds the at least one integrated circuit element.

17. The method of claim 16, further comprising the step of attaching a lid to the at least one encapsulant dam of the leadframe defining an air-cavity chamber of the integrated circuit device.

18. The method of claim 14, further comprising the step of at least partially covering the integrated circuit device with encapsulant forming a package body.

19. The method of claim 14, wherein, in the step of electrically connecting the at least one integrated circuit element to the at least one lead of the leadframe, the wire-bonding process has a wire feed angle of approximately 30-50 degrees.

20. The method of claim 14, wherein the step of electrically connecting the integrated circuit comprises a wire-bonding process in which a bond is first placed on the at least one integrated circuit element and a bond is then placed on at least one lead of the leadframe.
